(19) United States
(12) Patent Application Publication
(10) Pub. No.: US 2014/0167590 A1
(43) Pub. Date: Jun. 19, 2014

(54) ENCLOSURE OF ELECTRONIC DEVICE WITH PAD ASSEMBLY

(71) Applicants: Hon Hai Precision Industry Co., Ltd., New Taipei (TW); Hong Fu Jin Precision Industry (WuHan) Co., Ltd., Wuhan (CN)

(72) Inventors: CHUNG CHAI, New Taipei (TW); ZHI-QIANG LI, Wuhan (CN); ZHI-LONG LI, Wuhan (CN)

(73) Assignees: HON HAI PRECISION INDUSTRY CO., LTD., New Taipei (TW); HONG FU JIN PRECISION INDUSTRY (WUHAN) CO., LTD., Wuhan (CN)

(21) Appl. No.: 14/034,582

(22) Filed: Sep. 24, 2013

(30) Foreign Application Priority Data
Dec. 19, 2012 (CN) 2012105537220

(51) Int. Cl. F16M 13/00; H05K 5/02

(52) U.S. Cl. CPC F16M 13/005; H05K 5/02
USPC 312/351.1; 248/688

(57) ABSTRACT

A pad assembly includes a moving member and foot pad. The moving member is movable along a first direction. The guiding slot is defined in the moving member. The guiding slot includes an entrance slot, a positioning slot, and an exit slot. The entrance slot, the positioning slot, and the exit slot are connected end to end in sequence. The foot pad is movable along a second direction. The second direction is substantially perpendicular to the first direction. The guiding post protrudes from the foot pad and is movable in the guiding slot. Thee foot pad is movable from a first position where the guiding post is located between the entrance slot and the exit slot, to a second position where the guiding post is retained in the positioning slot, through the entrance slot.

### BACKGROUND

1. Technical Field

The disclosure generally relates to an enclosure of electronic devices, especially to an enclosure of an electronic device with pad assembly.

2. Description of Related Art

Electronic device, such as computer, printer, may be located in different places. To stably position the electronic devices, especially some thin electronic devices, such as thin computers, or thin printers, a foot bracket is mounted to a bottom of the electronic device to enhance a standing area of the electronic devices. However, the conventional foot bracket may occupy a large space when not in use. There is room for improvement within the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric, cutaway view of an enclosure of an electronic device in one embodiment.

FIG. 2 is similar to FIG. 1, but shown from another aspect.

FIG. 3 is an isometric view of a moving member of the enclosure of FIG. 1.

FIG. 4 is an assembled, cutaway view of a bottom wall, a foot base, and two foot pads of the enclosure of FIG. 1.

FIG. 5 is plan, sketching view of the moving member and the two foot pads of FIG. 4.

FIG. 6 is similar to FIG. 5, but the two foot pads are moved to each other.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

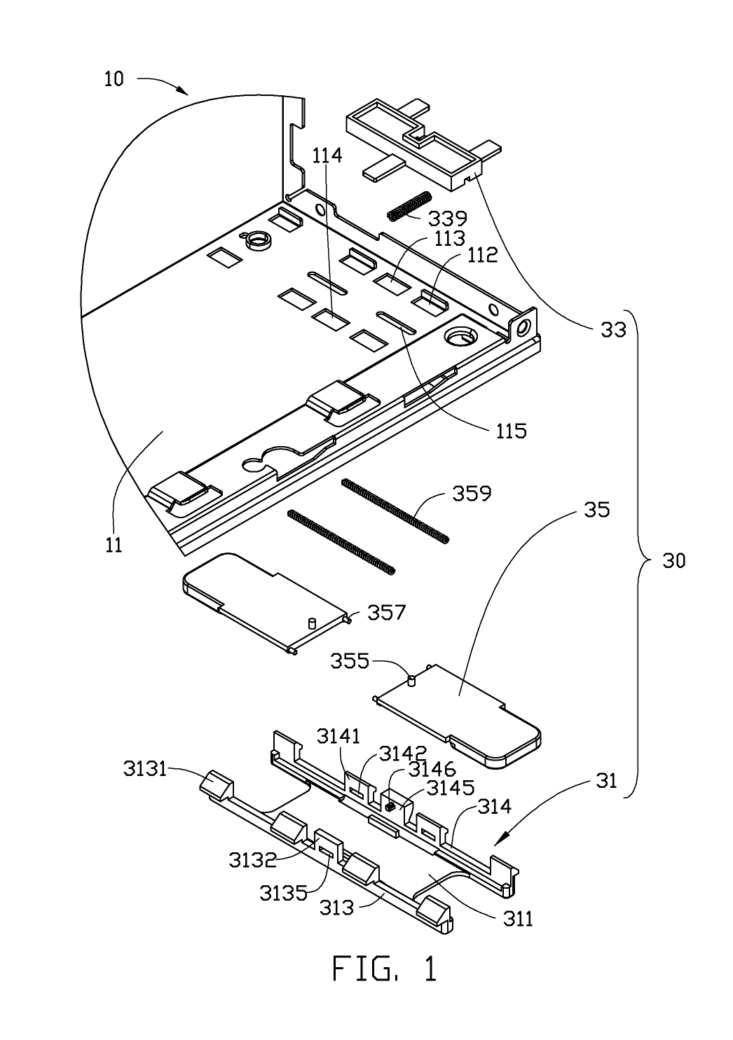

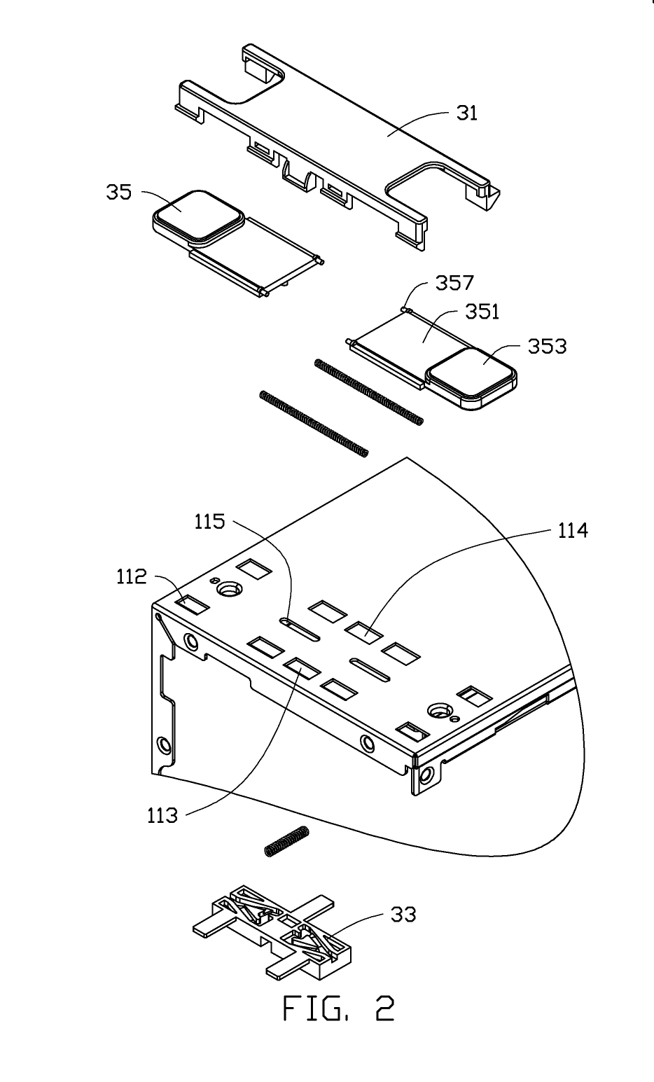

FIG. 1 and FIG. 2 illustrate two exploded views of an enclosure 10 of an electronic device. The enclosure 10 includes a bottom wall 11, a foot base 31, a moving member 33, and two foot pads 35.

A first through hole 113, a plurality of locking holes 112, a second through hole 114, two through slots 115 are defined in the bottom wall 11.

The foot base 31 includes a first strip 313, a second strip 314, and a connecting board 311, connecting the first strip 313 and the second strip 314. A guiding tab 3132 and a plurality of first hooks 3131 are located on the first strip 313. A first guiding hole 3135 is defined in the guiding tab 3132. A stand 3145 and a plurality of second hooks 3141 are located on the second strip 314. A protrusion 3146 protrudes from the stand 3145. Two second guiding holes 3142 are defined in two of the plurality of the second hooks 3141.

Each of the two foot pads 35 includes an extending board 351 and a supporting portion 353. Two pins 357 protrude from a later side of the extending board 351. A guiding post 355 protrudes from a bottom surface of the extending board 351.

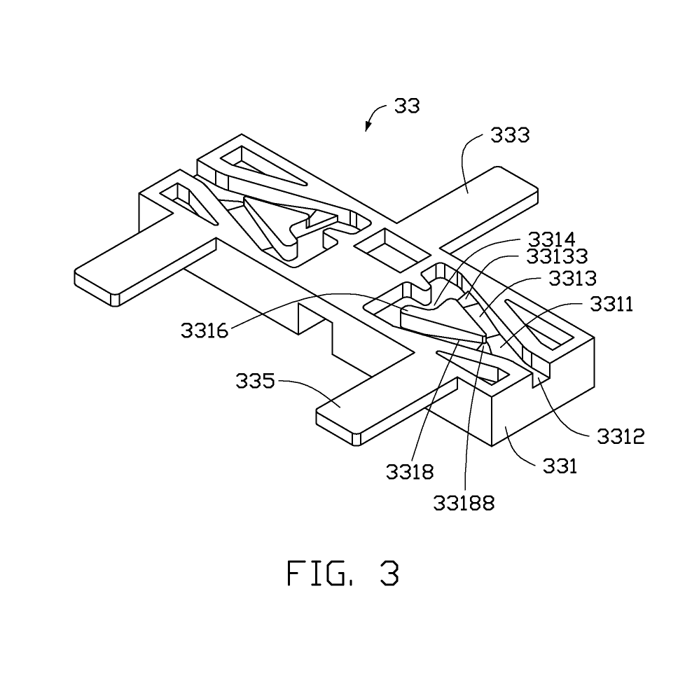

FIG. 3 illustrates an isometric view of the moving member 33. The moving member 33 includes a body 331, a first slide bar 333, and two second slide bars 335. The extending direction of the first slide bar 333 is opposite to the extending directions of the second slide bars 335. Two guiding slots 3311 are defined in the body 331. Each guiding slot 3311 includes an entrance slot 3313, a positioning slot 3314, and an exit slot 3318. The entrance slot 3313, the positioning slot 3314, and the exit slot 3318 are connected end to end in sequence. An entry opening 3312 is defined in the exit slot 3318 and the entrance slot 3313. A bottom surface of the entrance slot 3313 rises up along a direction from the exit slot 3318 to the positioning slot 3314. A first tab 33133 is located in the entrance slot 3313, adjacent to the positioning slot 3314. A bottom surface of the exit slot 3318 extends up along a direction from the positioning slot 3314 to the entrance slot 3313. A second tab 33188 is located in the exit slot 3318 adjacent to the entrance slot 3313. A block portion 3316 is located in the positioning slot 3314. The positioning slot 3314 is substantially M-shaped.

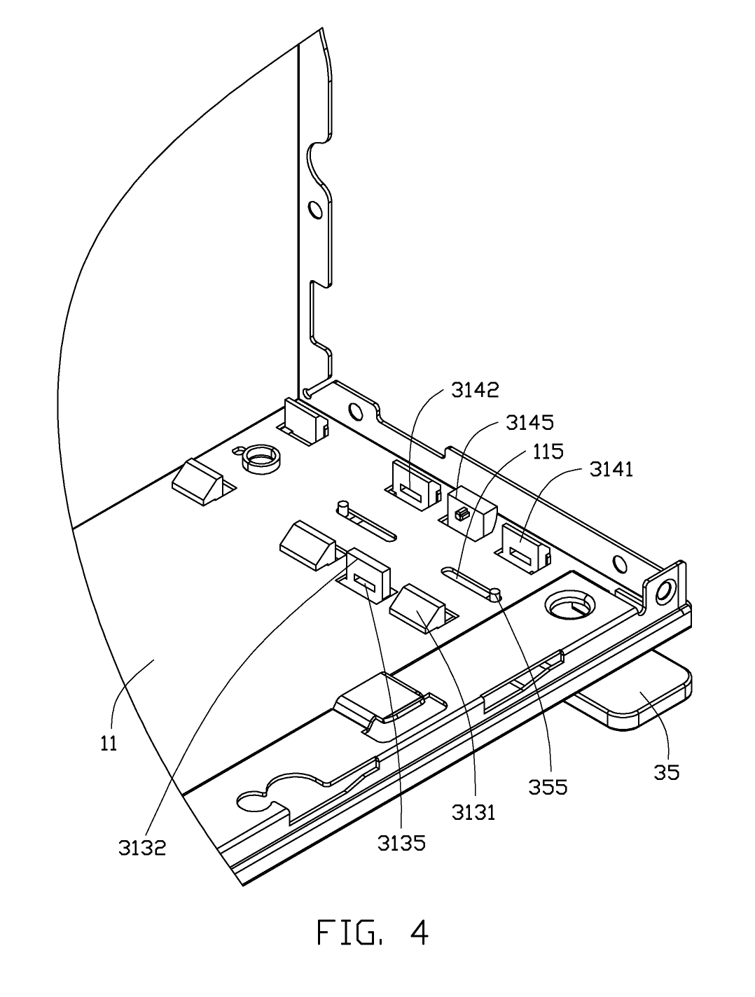

FIG. 4 illustrates an assembly view of the bottom wall 11, the foot base 31, and the two foot pads 35. The foot base 31 is attached to a bottom surface of the bottom wall 11. The first hooks 3131 and the second hooks 3141 are engaged in the plurality of locking holes 112. The stand 3145 extends through the first through hole 113. The guiding tab 3132 extends through the second through hole 114. The two foot pads 35 are located between the bottom wall 11 and the connecting board 311 of the foot base 31. Each guiding post 355 extends through each through slot 115. Two first springs 359 are located between the two foot pads 35 and engage with the four pins 357. The first slide bar 333 extends through the first guiding hole 3135. The two second slide bars 335 extend through the two guiding holes 3124. A second spring 339 is engaged with the protrusion 3146 and is located between the stand 3145 and the moving member 33 to resiliently urge the moving member 33 away from the stand 3145.

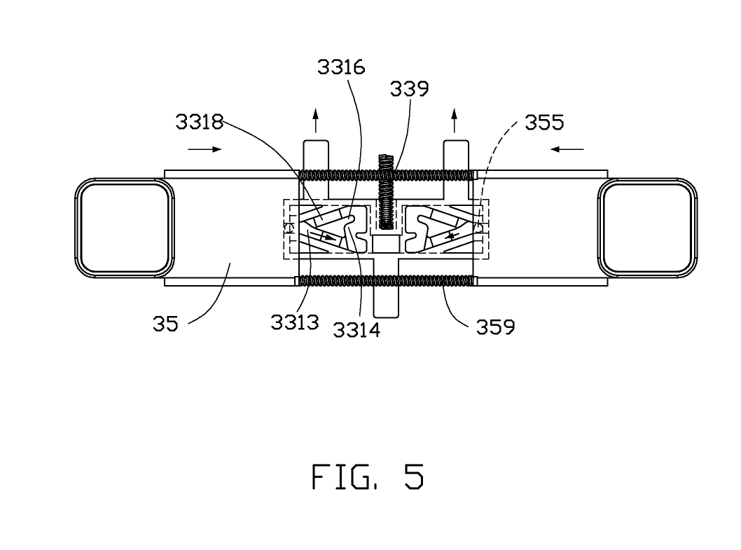

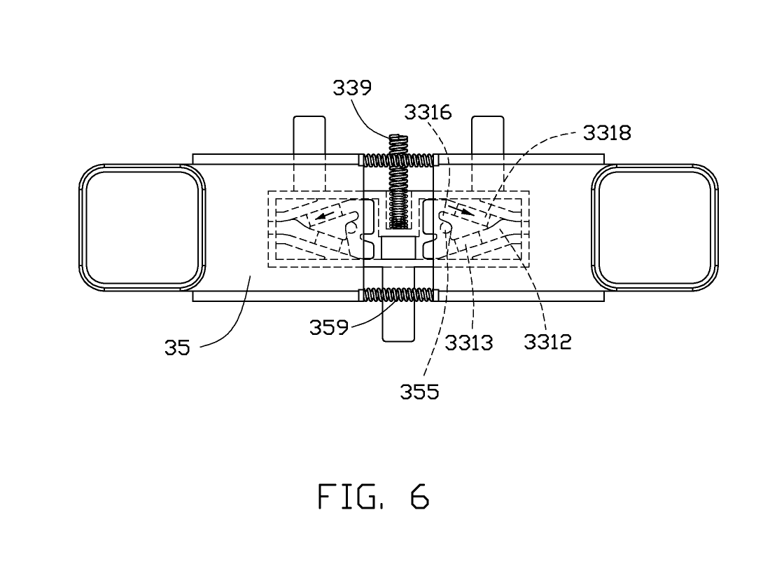

FIG. 5 and FIG. 6 illustrate two sketching views of the moving member 33 and the two foot pads 35. In use, the two foot pads 35 can move towards each other. The guiding post 355 of each foot pad 35 enters into the guiding slot 3311 of the moving member 33. When the two foot pads 35 are pushed toward each other, the guiding post 355 goes into the entrance slot 3313. The moving member 33 is held by the guiding post 355. When the guiding post 355 rides over the first tab 33133, the guiding post 355 goes into the positioning slot 3314, and the moving member 33 is moved by the second spring 339. The guiding post 355 is blocked by the block portion 3316 in the positioning slot 3314. The two first springs 359 are pressed and the two foot pads 35 go under the bottom wall 11 of the enclosure 10.

When opening the two foot pads 35, the two foot pads 35 are further pushed toward each other. The guiding post 355 goes beyond the block portion 3316 and moves from the positioning slot 3314 to the exit slot 3318. The two first springs 359 rebound and push away the two foot pads 35. The guiding post 355 moves back to the entrance slot 3313 riding over the second tab 33188. The two foot pads 35 are opened.

It is also understood, that even though numerous characteristics and advantages have been set forth in the foregoing description of preferred embodiments, together with details of the structures and functions of the preferred embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A pad assembly, comprising:
a moving member movable along a first direction; a guiding slot, defined in the moving member, comprising an entrance slot, a positioning slot, and an exit slot; and the entrance slot, the positioning slot, and the exit slot being connected end to end in sequence; and
a foot pad movable along a second direction; the second direction being substantially perpendicular to the first direction and a guiding post protruding from the foot pad and being movable in the guiding slot;
wherein the foot pad is movable from a first position where the guiding post is located between the entrance slot and the exit slot, to a second position where the guiding post is retained in the positioning slot, through the entrance slot; and the foot pad is further movable from the second position back to the first position and the guiding post moves through the exit slot.

2. The pad assembly of claim 1, wherein a bottom surface of the entrance slot extends up along a direction from the exit slot to the positioning slot.

3. The pad assembly of claim 2, wherein a first tab is located in the entrance slot to prevent the guiding post from moving from the positioning slot to the entrance slot.

4. The pad assembly of claim 1, wherein a bottom surface of the exit slot extends up along a direction from the positioning slot to the entrance slot.

5. The pad assembly of claim 4, wherein a second tab is located in the exit slot to prevent the guiding post from moving from the entrance slot to the exit slot.

6. The pad assembly of claim 1, further comprising a foot base, wherein the moving member and the foot pad are attached to the foot base.

7. The pad assembly of claim 6, wherein a resilient element is located between the moving member and the foot base.

8. An enclosure of an electronic device, comprising:
a bottom wall; and
a pad assembly comprising:
a foot base attached to the bottom wall;
a moving member attached to the foot base and being movable along a first direction, a guiding slot defined in the moving member, comprising an entrance slot, a positioning slot, and an exit slot; and the entrance slot, the positioning slot, and the exit slot being connected end to end in sequence; and
a foot pad movable along a second direction, the second direction being substantially perpendicular to the first direction and a guiding post protruding from the foot pad and being movable in the guiding slot;
wherein the foot pad is movable from a first position where the guiding post is located between the entrance slot and the exit slot, to a second position where the guiding post is retained in the positioning slot, through the entrance slot; and the foot pad is further movable from the second position back to the first position and the guiding post moves through the exit slot.

9. The enclosure of an electronic device of claim 8, wherein a bottom surface of the entrance slot rises up along a direction from the exit slot to the positioning slot.

10. The enclosure of an electronic device of claim 9, wherein a first tab is located in the entrance slot to prevent the guiding post from moving from the positioning slot to the entrance slot.

11. The enclosure of an electronic device of claim 8, wherein a bottom surface of the exit slot extends up along a direction from the positioning slot to the entrance slot.

12. The enclosure of an electronic device of claim 11, wherein a second tab is located in the exit slot to prevent the guiding post from moving from the entrance slot to the exit slot.

13. The enclosure of an electronic device of claim 8, wherein the foot pad is located between the bottom wall and the foot base.

14. The enclosure of an electronic device of claim 13, wherein the bottom wall is located between the moving member and the foot pad.

15. The enclosure of an electronic device of claim 8, wherein a resilient element is located between the moving member and the foot base.

16. The enclosure of an electronic device of claim 15, wherein a through slot is defined in the bottom wall along the second direction, and the guiding post extending through the through slot.
